(19) United States
(12) Patent Application Publication
(10) Pub. No.: US 2025/0237574 A1
(43) Pub. Date: Jul. 24, 2025

(54) EVALUATION DEVICE, ROUGH SURFACE, EVALUATION METHOD, AND PROGRAM

(71) Applicant: TOHOKU UNIVERSITY, Sendai-shi, Miyagi (JP)

(72) Inventor: Aiko YAKENO, Sendai-shi (JP)

(21) Appl. No.: 18/881,848

(22) PCT Filed: May 31, 2023
(86) PCT No.: PCT/JP2023/020386

§ 371 Date: Jan. 7, 2025

Related U.S. Application Data
(60) Provisional application No. 63/389,369, filed on Jul. 15, 2022.

(51) Int. Cl. G01M 9/08; G06F 30/28

(52) U.S. Cl. CPC G01M 9/08; G06F 30/28

(57) ABSTRACT

An evaluation device for evaluating a test section, in which a laminar flow transitions to a turbulent flow, of a rough surface on which a fluid flows includes: an acquisition unit configured to acquire a thickness of a laminar boundary layer at an inlet of the test section; a calculation unit configured to calculate turbulent energy and a flow direction distribution of frictional resistance coefficient values at the rough surface by performing a direct numerical simulation based on the acquired thickness of the laminar boundary layer; and an output unit configured to output information based on a result of calculation.

### TECHNICAL FIELD

The present invention relates to an evaluation device, a rough surface, an evaluation method, and a program.

### BACKGROUND ART

In the related art, there has been known a technique of performing riblet processing along a direction in which a fluid flows, as a technique for reducing frictional drag of a fluid. By performing riblet processing, it is possible to reduce the frictional drag for a fluid flowing in a predetermined direction. However, when the flow direction of the fluid and the direction of the riblet processing deviate from each other by a predetermined angle or more, the frictional drag contrarily increases. A technique of delaying natural transition by a protrusion having small waveform roughness to reduce frictional resistance has been known. As described, a relationship between a shape of a surface on which a fluid flows and an increase in frictional drag has been actively studied (see, for example, NPL 1).

### CITATION LIST

### Non Patent Literature

NPL 1: Y. Kuwata and R. Nagura, Direct numerical simulation on the effects of surface slope and skewness on rough-wall turbulence, “Physics of Fluids”, USA, AIP Publishing, Oct. 8, 2020, 32, 105113-1-15

### SUMMARY OF INVENTION

### Technical Problem

However, according to studies in the related art, there has been little research on a rough surface for reducing frictional drag.

The invention has been made in view of such circumstances, and an object of the invention is to provide an evaluation device, an evaluation method, and a program capable of clarifying a mechanism of reducing frictional drag by fine distribution roughness. Further, an object of the invention is to provide a rough surface, which is capable of reducing frictional drag, by using the evaluation device, the evaluation method, and the program.

### Solution to Problem

[1] According to an aspect of the invention, there is provided an evaluation device for evaluating a test section, in which a laminar flow transitions to a turbulent flow, of a rough surface on which a fluid flows, the evaluation device including: an acquisition unit configured to acquire a thickness of a laminar boundary layer at an inlet of the test section; a calculation unit configured to calculate turbulent energy and a flow direction distribution of frictional drag coefficient values at the rough surface by performing a direct numerical simulation based on the acquired thickness of the laminar boundary layer; and an output unit configured to output information based on a result of calculation.
[2] According to an aspect of the invention, in the evaluation device according to the above [1], the calculation unit calculates the turbulent energy and the flow direction distribution of frictional drag coefficient values at the rough surface by using a volume penalization method (VP method) and a zonal method.
[3] According to an aspect of the invention, in the evaluation device according to the above [1] or [2], the acquisition unit acquires the thickness of the laminar boundary layer at the inlet of the test section based on an image obtained by imaging the rough surface.
[4] According to an aspect of the invention, the evaluation device according to any one of the above [1] to [3] further includes a specifying unit configured to specify a position of transition from the laminar flow to the turbulent flow based on the calculated turbulent energy and flow direction distribution of frictional resistance coefficient values at the rough surface, in which the output unit outputs the specified position of transition.
[5] According to an aspect of the invention, the evaluation device according to any one of the above [1] to [4] further includes a selection unit, in which the acquisition unit acquires the thickness of the laminar boundary layer at the inlet of the test section for a plurality of the rough surfaces, the calculation unit calculates the turbulent energy and the flow direction distribution of frictional drag coefficient values at each of the plurality of the rough surfaces by performing a direct numerical simulation based on the acquired thicknesses of the plurality of laminar boundary layers, and the selection unit selects the rough surface, which is capable of inhibiting growth of a vortex and destroying a generated vortex, based on the calculated turbulent energy and flow direction distribution of frictional drag coefficient values at each of the plurality of the rough surfaces.
[6] According to an aspect of the invention, in the evaluation device according to the above [5], the selection unit decomposes variables of a Navier-Stokes equation into a time-invariant variable and a time-variant variable, and selects, based on a wavelength of a vortex amplified when a random number is given as a disturbance, the rough surface capable of inhibiting growth of a vortex and promoting nullification by destroying a generated vortex.
[7] According to an aspect of the invention, there is provided a rough surface that is a rough surface on which a fluid flows, in which the rough surface is selected by the evaluation device according to the above [5] or [6].
[8] According to an aspect of the invention, the rough surface according to the above [7] includes: a first protrusion based on a first wavelength that is a wavelength capable of inhibiting growth of a vortex; and a second protrusion based on a second wavelength that is a wavelength different from the first wavelength and is capable of promoting destruction of a generated vortex, in which the first protrusion and the second protrusion are provided in both of a first direction and a second direction, the first direction being in parallel to the rough surface and being a vortex advection direction, the second direction being in parallel to the rough surface and orthogonal to the first direction.
[9] According to an aspect of the invention, there is provided an evaluation method for evaluating a test section, in which a laminar flow transitions to a turbulent flow, of a rough surface on which a fluid flows, the evaluation including: an acquisition step of acquiring a method thickness of a laminar boundary layer at an inlet of the test section; a calculation step of calculating turbulent energy and a flow direction distribution of frictional drag coefficient values at the rough surface by performing a direct numerical simulation based on the acquired thickness of the laminar boundary layer; and an output step of outputting information based on a result of calculation.

According to an aspect of the invention, there is provided a program for evaluating a test section, in which a laminar flow transitions to a turbulent flow, of a rough surface on which a fluid flows, the program causing a computer to execute: an acquisition step of acquiring a thickness of a laminar boundary layer at an inlet of the test section; a calculation step of calculating turbulent energy and a flow direction distribution of frictional drag coefficient values at the rough surface by performing a direct numerical simulation based on the acquired thickness of the laminar boundary layer; and an output step of outputting information based on a result of calculation.

### Advantageous Effects of Invention

According to the invention, it is possible to provide an evaluation device, an evaluation method, and a program capable of clarifying a mechanism of reducing frictional drag by fine distribution roughness. Further, the invention can provide a rough surface, which is capable of reducing frictional drag, by using the evaluation device, the evaluation method, and the program.

### BRIEF DESCRIPTION OF DRAWINGS

FIG. 1 is a diagram illustrating a test section to be evaluated by an evaluation device according to an embodiment.

FIG. 2 is a diagram illustrating boundary conditions according to the embodiment.

FIG. 3 is a diagram illustrating an example of a mask function shape and a grid resolution in the vicinity of a wall according to the embodiment.

FIG. 4 is a diagram illustrating an example of a zonal grid used by the evaluation device according to the embodiment.

FIG. 5 is a diagram illustrating a geometric shape of a rough surface according to the embodiment.

FIG. 6 is a diagram illustrating an example of visualization of a simulation result by the evaluation device according to the embodiment.

FIG. 7 is a contour map for illustrating comparison of turbulent kinetic energy for each type of rough surface according to the embodiment.

FIG. 8 is a diagram illustrating a maximum value of turbulent kinetic energy along an x direction for each type of rough surface according to the embodiment.

FIG. 9 is a diagram illustrating a change along the X direction, regarding a decomposition integral value of the turbulent kinetic energy in a Z direction and a frictional drag coefficient value according to the embodiment.

FIG. 10 is a diagram illustrating a snap shot for each type of rough surface according to the embodiment and illustrating a plurality of snap shots at different time-points.

FIG. 11 is a contour map of turbulent kinetic energy averaged in phase, time, and span of a T-S wave component according to the embodiment.

FIG. 12 is a contour map of turbulent kinetic energy averaged in phase, time, and span of a T-S wave component three-dimensional structure according to the embodiment.

FIG. 13 is a functional configuration diagram illustrating an example of a functional configuration of the evaluation device according to the embodiment.

FIG. 14 is a flowchart illustrating an example of an evaluation method according to the embodiment.

FIG. 15 is a block diagram illustrating an example of an internal configuration of an evaluation device 10 according to the embodiment.

### DESCRIPTION OF EMBODIMENTS

### Embodiments

An evaluation device, a rough surface, an evaluation method, and a program according to aspects of the invention will be described in detail below with reference to preferred embodiments and the accompanying drawings. It should be noted that the aspects of the invention are not limited to these embodiments, and various modifications and improvements are also included. That is, the components described below include those easily conceivable by those skilled in the art and substantially the same components, and the components described below can be appropriately combined. Further, various omissions, substitutions, and changes of the components can be made without departing from the gist of the invention. Further, in the following drawings, in order to facilitate the understanding of each configuration, the scale, the number, and the like of each structure may be different from the scale, the number, and the like of an actual structure.

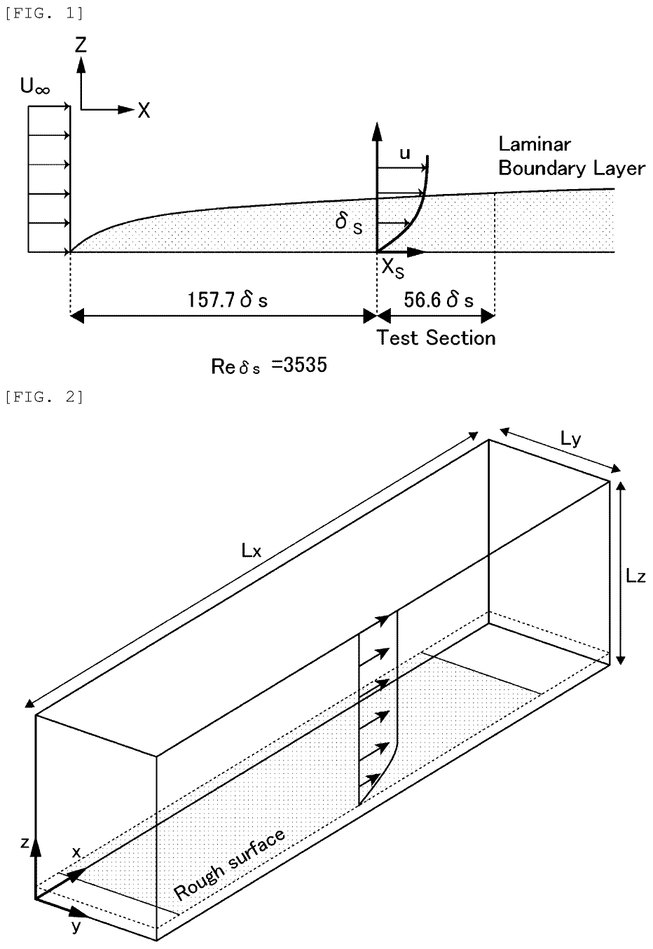

FIG. 1 is a diagram illustrating a test section to be evaluated by an evaluation device according to an embodiment. In the drawing, a boundary layer developed on a flat plate is shown. More specifically, a laminar boundary layer formed by a laminar flow is shown in the drawing. It has been known that the boundary layer is strongly affected by viscosity. In the illustrated example, a left direction is defined as an upstream side and a right direction is defined as a downstream side, and a fluid flows from the upstream side to the downstream side. As the fluid flowing from the upstream side to the downstream side, the flow transitions from the laminar flow (a state in which frictional drag is small due to a stable flow) to a turbulent flow (a state in which the frictional drag is large due to a turbulent flow). On the downstream side (not shown) of the laminar boundary layer as shown in the drawing, a turbulent boundary layer is formed following a transition region. By using the evaluation device according to the embodiment to provide a rough surface capable of restricting and destroying growth of a vortex in the transition, it is possible to reduce the overall frictional drag.

Whether the flow is a laminar flow or a turbulent flow can be determined based on the magnitude of turbulent energy. An increase in turbulent energy on the downstream side means that a transition from the laminar flow to the turbulent flow occurs. The frictional drag itself is evaluated more directly by Reynolds stress than by the turbulent energy. It has been known that the turbulent energy and the Reynolds stress have generally high correlation.

In general, it has been known that such a surface subjected to riblet processing is effective for a flow that develops into a turbulent flow. An object is to perform evaluation on a region, which includes a transition region from a laminar flow to a turbulent flow and a turbulent flow region, by the evaluation device according to the embodiment to obtain an effect for the region. That is, it can be said that unstable modes are different between a technique in the related art such as the riblet and a rough surface provided by the evaluation device according to the embodiment. In the following description, a section to be evaluated by the evaluation device according to the embodiment may be referred to as a test section. The test section can also be said to be a section, which includes a transition region from a laminar flow to a turbulent flow and a turbulent flow region, of a rough surface on which fluid flows.

In the drawing, a velocity distribution of the fluid at an inlet part of the test section is shown. In general, due to the viscosity of the fluid, the velocity of the fluid is lower as the fluid is closer to an object surface, with the velocity being 0 at the surface, and the velocity of the fluid is higher as the fluid is farther from the surface. In the laminar boundary layer, since there is little mixing of upper and lower layers, flow separation tends to occur, and since there is little mixing, the frictional drag is reduced. That is, in the laminar boundary layer, the frictional drag is small, and thus a velocity distribution in which the velocity gently decreases in accordance with a distance from the object surface is presented. In the turbulent boundary layer, a region near the object surface, in which the velocity of the fluid is low, is called a viscous sub-layer or an inner layer. A region far from the object surface, in which the velocity of the fluid is high, is called a turbulent layer or an outer layer. Further, a region between the viscous sub-layer and the turbulent layer is called a buffer layer.

In the drawing, a thickness of the laminar boundary layer at an inlet of the test section is denoted as os. The evaluation device according to the embodiment performs a direct numerical simulation (DNS) based on os to calculate the turbulent energy and a flow direction distribution of frictional drag coefficient values at the rough surface.

The fluid to be evaluated by the evaluation device according to the embodiment broadly includes water, oil, air, and the like. A width of the boundary layer (including the viscous sub-layer in a turbulent state) is determined depending on a composition of the fluid. The frictional drag can be reduced even when the rough surface provided by using the evaluation device according to the embodiment has a roughness height equivalent to or smaller than a width of the viscous sub-layer in the turbulent state. According to the rough surface provided by using the evaluation device according to the embodiment, according to the rough surface provided by using the evaluation device according to the embodiment, it is possible to reduce kinetic energy causing the transition of laminar flow and turbulent flow, and to reduce the frictional drag by delaying the transition and restricting regeneration of the turbulent flow. Further, in the turbulent state, kinetic energy of the fluid is stably consumed in a region extremely close to the surface by fine rough surfaces distributed like sands having a size equivalent to or smaller than that of the viscous sub-layer. The rough surface provided by using the evaluation device according to the embodiment can also be said to have a structure capable of obtaining such an effect.

FIG. 2 is a diagram illustrating boundary conditions in the embodiment. In the drawing, a rough surface to be evaluated by the evaluation device according to the embodiment is shown. As illustrated, it is assumed that the rough surface is arranged along an x-y plane. A direction perpendicular to the rough surface is referred to as a z direction. In order to handle a finite calculation domain in the numerical calculation, it is preferable to apply appropriate boundary conditions. Since the boundary layer is formed in the flow on the rough surface, the closer to the rough surface, the smaller a grid spacing may be provided. Further, since a flow field gets close to a steady mainstream from the rough surface to a far side, the grid spacing may be gradually widened. That is, grid stretching may be performed.

The boundary conditions used for the calculation by the evaluation device according to the embodiment will be described. According to the embodiment, since a turbulent flow transition process is analyzed by performing a three-dimensional direct numerical simulation, the calculation cost is reduced and the calculation domain is efficiently set, which is preferred. The Reynolds number based on a thickness δs of the laminar boundary layer at the inlet is set to 3535. In order to obtain a sufficiently large time increment within a range where a compressibility effect can be ignored, a Mach number is set to 0.2. Displacement is nondimensionalized by the thickness of the boundary layer at an inlet boundary, and a calculation domain in the flow direction is 56.6.

In an inlet boundary condition, a flow direction velocity and a wall vertical direction velocity obtained by a Brasius laminar solution are assigned, and a density and a pressure are set to the same value as the mainstream. In the inlet boundary condition, an artificial disturbance is added to a wall surface normal velocity to induce a Tollmien-Schlichting (T-S) wave. In order to analyze the influence of the rough surface after the artificial disturbance is received by the boundary layer, the rough surface may be disposed at a location away from the inlet boundary. A calculation domain in a spanwise direction may be determined based on two-point correlation of a ω dash (a fluctuation component of a height direction velocity). A periodic condition is applied to a boundary in the spanwise direction.

At an outlet boundary, the velocity and the pressure are assumed to be free. At a far boundary in a wall-normal direction, a pressure and a flow velocity are fixed, and flow velocities in the wall-normal direction and the spanwise direction are assumed to be free. Regarding the outlet boundary, a density, the velocity, and the pressure are defined as free conditions (Dirichlet boundary conditions). At a far boundary in the wall-normal direction, a pressure and a streamwise velocity are fixed to values of a free flow, and the wall-normal direction velocity and a spanwise direction velocity are defined as free conditions. At a wall surface boundary, a no-slip condition is applied and velocities in all directions are fixed to 0. Further, it is assumed that a heat insulating wall condition is satisfied, and gradients of a density and a pressure are set to zero in the wall-normal direction.

The evaluation device according to the embodiment reproduces a rough surface of a three-dimensional shape by using a volume penalization method (VP method). The VP method of a compressible flow can impart a no-slip condition to any fixed wall shape by adding a penalty term to a Navier-Stokes equation that is a dominant equation. By using the VP method, it is not necessary to generate a grid fitted to a solid wall, and a wall having any shape can be analyzed.

The Navier-Stokes equation to which the penalty term is added is expressed by the following formulas (1) to (3).

$$[ Math . 1 ]$$

$$\frac{\partial p}{\partial t} + \frac{\partial ( ρ {u}_{j} )}{\partial {x}_{j}} = - ( \frac{1}{ϕ} - 1 ) χ \frac{\partial ( ρ {u}_{j} )}{\partial {x}_{j}} , \qquad ( 1 )$$

$$[ Math . 2 ]$$

$$\frac{\partial ( ρ {u}_{j} )}{\partial t} + \frac{\partial ( ρ {u}_{i} {u}_{j} )}{\partial {x}_{j}} = - \frac{\partial p}{\partial {x}_{i}} + \frac{\partial {τ}_{ij}}{\partial {x}_{j}} - \frac{χ}{η} ( {u}_{i} - {U}_{0 , i} ) . \qquad ( 2 )$$

$$[ Math . 3 ]$$

$$\frac{\partial e}{\partial t} + \frac{\partial }{\partial {x}_{j}} [ ( e + p ) {u}_{j} ] = \frac{\partial ( {u}_{i} {τ}_{ij} )}{\partial {x}_{j}} + \frac{\partial }{\partial {x}_{j}} ( κ \begin{matrix}\partial T \\ \partial {x}_{j}\end{matrix} ) - \frac{χ}{{η}_{T}} ( T - {T}_{0} ) , \qquad ( 3 )$$

Here, ρ is the density of the fluid, uᵢ is the flow velocity, and U_{0,i} is a solid wall speed and is set to 0 in order to impose a no-slip condition. Further, φ is a porosity and is set to 1.0. Further, κ is thermal conductivity, τᵢⱼ is a viscosity stress, and ν is a permeability, all of which are set to sufficiently small values. Further, ν_{T} is a thermal permeability and is assumed to be the same as ν. Further, e is total energy, p is the pressure, T is a temperature, and T₀ is a solid wall temperature. According to the embodiment, since a temperature change can be ignored in the flow of a low Mach number, the solid wall temperature is assumed to be the same as that of the mainstream. Further, since χ is a mask function and the VP method does not require generation of a boundary matching grid, it is possible to reproduce a solid wall of any shape by defining the mask function by the following formula (4).

$$[ Math . 4 ]$$

$$χ ( x ) - \{ \begin{matrix}1 & ( Solid wall ) \\ 0 & ( Fluid )\end{matrix} \qquad ( 4 )$$

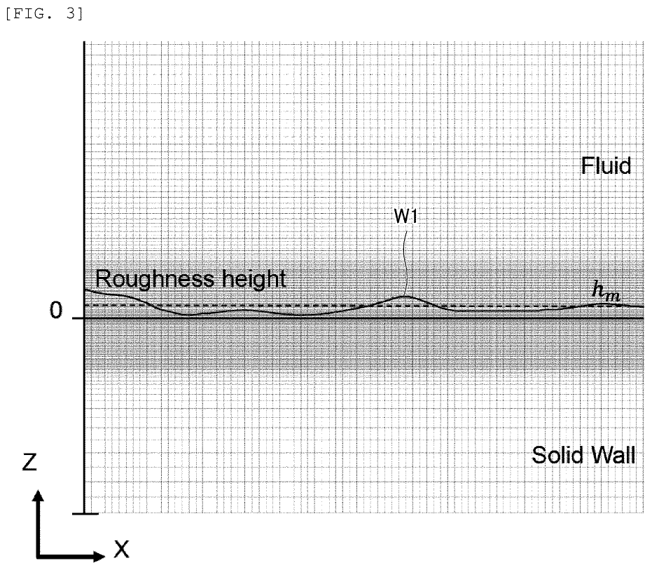

FIG. 3 is a diagram illustrating an example of a mask function shape and a grid resolution in the vicinity of a wall according to the embodiment. A line W1 shown in the drawing indicates a roughness height in the fluid, and a broken line indicates an average roughness height hm. Thus, since the mask function is defined on an orthogonal grid, it is preferable to resolve the roughness at a sufficient number of grid points in both the streamwise direction and the wall-normal direction in order to reproduce the shape of the fixed wall. The resolution is preferably about 20 points or more per one wavelength of roughness.

The VP method offsets from an origin in the wall-normal direction and an end of a computational grid to ensure the number of grid points inside the wall surface. That is, the calculation is performed by defining a lower side of the line W1 in the drawing as an individual wall and an upper side as a fluid region.

Here, in order to reproduce the shape of the rough surface with an orthogonal grid, it is preferable to use a sufficiently fine grid resolution. However, when such a calculation is performed on the entire calculation domain, an enormous calculation cost is required. Therefore, in the embodiment, a zonal method is applied in order to capture a turbulent flow with high accuracy while restricting the calculation cost. The zonal method is a method of performing numerical calculations using two or more computational grids. By applying the zonal method, it is possible to perform calculation of a complicated shape difficult with a single computational grid, or to perform calculation by locally increasing the grid resolution. For example, the zonal method is used for detailed flow field analysis of an intake internal flow in a supersonic machine in a main wing of an aircraft and the like, and for analysis around a plasma actuator installed at a front edge of the main wing.

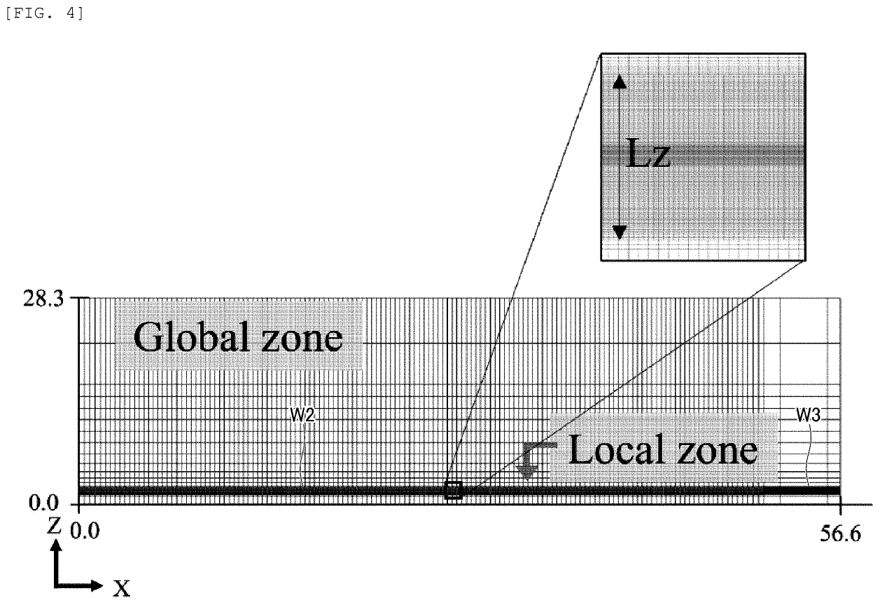

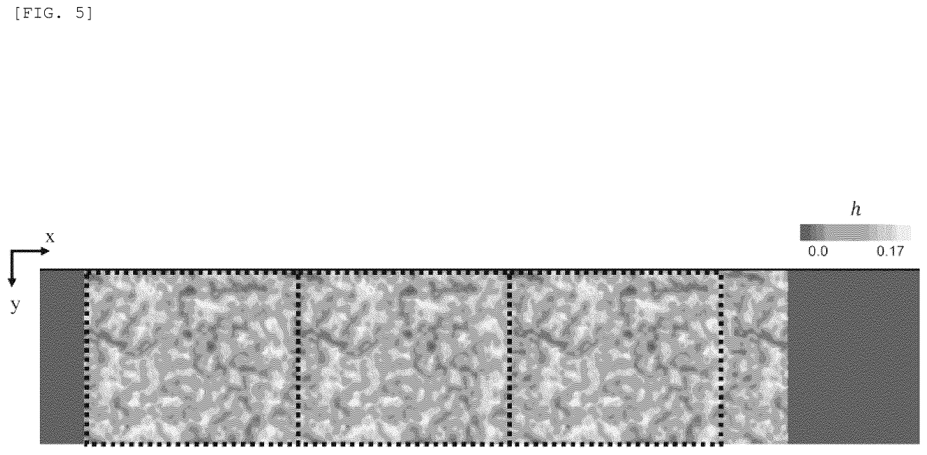

FIG. 4 is a diagram illustrating an example of a zonal grid used by the evaluation device according to the embodiment. In order to reproduce a shape of a wall surface shape, the evaluation device according to the embodiment preferably sets a locally high grid resolution in the vicinity of the wall. A region indicated by a line W2 in the drawing is a local zone, and a region indicated by a line W3 is a global zone. In the local zone, the grid resolution in the streamwise direction is two times that in the global zone. A height of the local zone is Lz⁺≈50 in viscous wall units, and includes a viscous sub-layer and a buffer layer in the turbulent boundary layer.

Specifically, the resolution of the global zone is (Nx, Ny, Nz)=(1454, 151, 284). A calculation domain length is (Lx, Ly, Lz)=(56.6, 11.3, 28.3) by the streamwise direction, the spanwise direction, and the wall-normal direction. On the other hand, the resolution of the local zone is specifically (Nx, Ny, Nz)=(2843, 201, 137). The calculation domain is (Lx, Ly, Lz)=(50.9, 11.3, 0.59). However, in a smooth surface and a wavy rough surface as comparative examples, Ny=201 and Ly=14.1 were used in the spanwise direction, and in the calculation for a sandy rough surface as the example, Ly=11.3 was used. This is because it is preferable to reduce the calculation domain in the spanwise direction since a high resolution is required to reproduce fine unevenness of the rough surface.

The evaluation device according to the embodiment may analyze the sandy rough surface based on data obtained by performing laser measurement on actual sandpaper. In the related art, it is known that a frictional drag coefficient value for a fully-developed turbulent flow depends on a roughness height. In recent years, attention has been focused on a fact that the frictional drag coefficient value for a fully-developed turbulent flow depends on an effective slope ES, which is a parameter for determining a shape of roughness, and skewness Sk. The effective slope ES and the skewness Sk of the rough surface provided by the evaluation device according to the embodiment are calculated by the following formulas (5) and (6).

$$[ Math . 5 ]$$

$$ES = \frac{1}{{L}_{x} {L}_{z}} {\int }_{x} {\int }_{z} \vert \frac{\partial h ( x , z )}{\partial x} dxdz . \qquad ( 5 )$$

$$[ Math . 6 ]$$

$$Sk = \frac{1}{{h}_{rms}^{3} {L}_{x} {L}_{z}} {\int }_{x} {\int }_{z} {( h ( x , z ) - {h}_{m} )}^{3} dxdz . \qquad ( 6 )$$

The skewness Sk is also referred to as a deviation degree, and is a parameter indicating a deviation in a distribution of hills and dales on a rough surface. For example, in a case where a presence probability distribution for each roughness height is considered, if Sk=0, the roughness distribution can be said to be symmetrical, if Sk>0, a ratio of hills can be said to be large, and if Sk<0, a ratio of dales can be said to be large. The effective slope ES is defined as an average value of the slope. The effective slope ES can also be referred to as a ratio of the roughness height to a roughness interval. In the case of a wavy rough surface, the effective slope ES can be expressed as ES=h/λ where h is a roughness height and A is a roughness wavelength.

In the embodiment, specifically, the skewness Sk=−0.097 and the effective slope ES=0.130 were used. It is known that a difference of δU+according to the value of the skewness Sk is small when the effective slope ES is relatively small, which suggests that a difference in the skewness Sk is not very important.

Specifically, the inventors used 1000 grit sandpaper roughness, scaled to a height of 0.092. Since it was found that there was an effect on the rough surface, a simulation using a Gaussian function was performed next, and it was found that a similar effect could be obtained. Here, in the case of sandpaper roughness, it is preferable to use a repetitive pattern since the entire calculation domain cannot be completely covered with a single piece of sandy roughness data. In the case of simulating using a Gaussian function, it is not necessary to use a repetitive pattern.

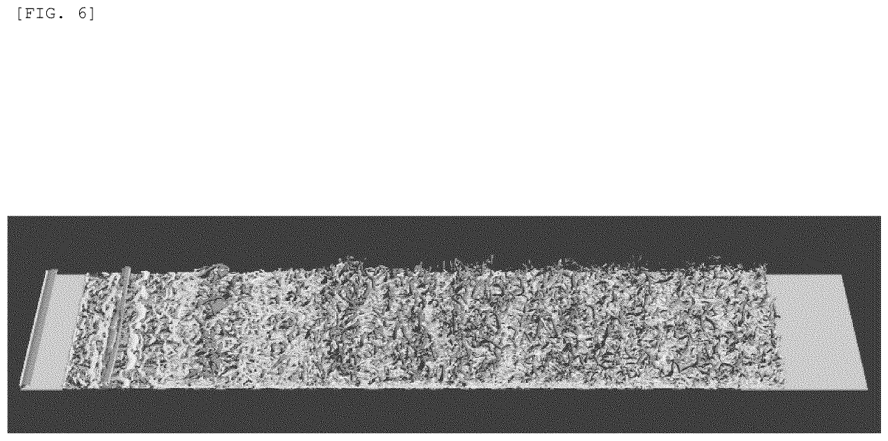

FIG. 5 is a diagram illustrating a geometric shape of a rough surface according to the embodiment. An example of a repetitive pattern will be described with reference to the drawing. A rectangle defined by a broken line in the drawing indicates one unit tile. By arranging unit tiles continuously, the entire calculation domain can be completely covered. As illustrated in the drawing, it can be seen that repeating boundaries of the rough surface are smoothly connected. The unit tiles are not limited to an example in which the unit tiles are continuously arranged in one direction as illustrated, and may be arranged continuously in two-dimensional directions.

Here, it is not easy to strictly determine a viscosity unit in the transition process. However, a viscosity scale is calculated from flow field data on a smooth surface, and the calculated viscosity scale is assumed to be a turbulent flow scale of the same degree of a rough surface, whereby a conversion to the viscosity scale can be performed. In this case, an average height in the embodiment was h+m=15.5.

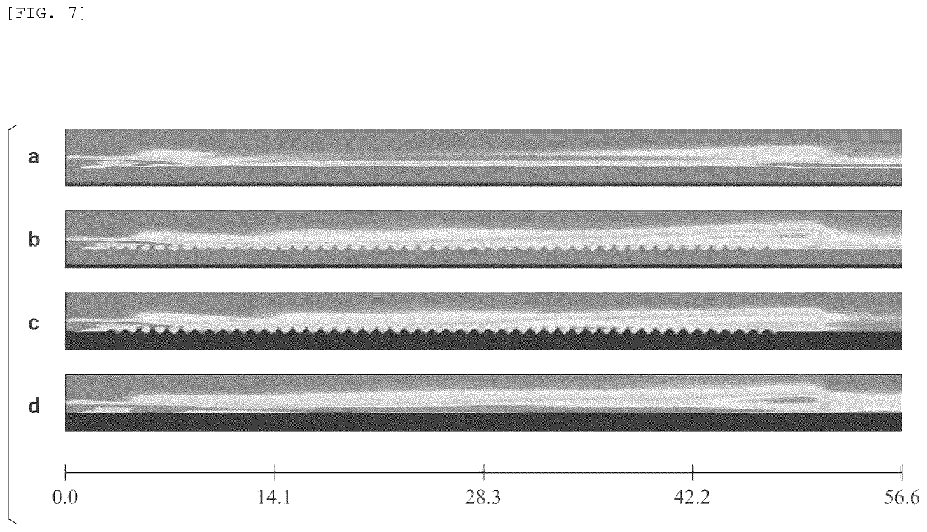

FIG. 6 is a diagram illustrating an example of visualization of a simulation result by the evaluation device according to the embodiment. In the drawing, a left side indicates an upstream side of the flow, and a right side indicates a downstream side. As illustrated in the drawing, a T-S wave, which is in a form of a two-dimensional roll vortex induced at an inlet boundary, is advected in a downstream direction, is soon distorted while being wavy in an orthogonal span depth direction, and collapses as a turbulent flow.

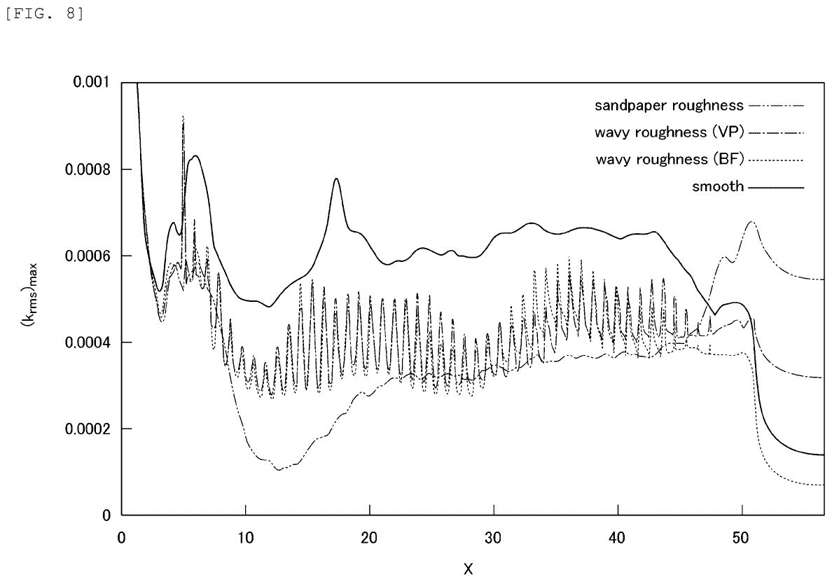

FIG. 7 is a contour map for illustrating comparison of turbulent kinetic energy for each type of rough surface according to the embodiment. In the drawing, vortices are visualized based on Q values in instantaneous fields of three rough surfaces. In the drawing, a left side indicates an upstream side of the flow, and a right side indicates a downstream side. (a) of FIG. 7 is an example of a sandy rough surface (sandy roughness, sandpaper roughness, or sand-grind roughness), and illustrates a case where a rough surface provided by the evaluation device according to the embodiment is used. (b) of FIG. 7 is an example of wavy roughness (VP method) and is a comparative example. (c) of FIG. 7 is an example of wavy roughness (body fitted grid), and is a comparative example. (d) of FIG. 7 is an example of a flat plate (smooth surface), and is a comparative example.

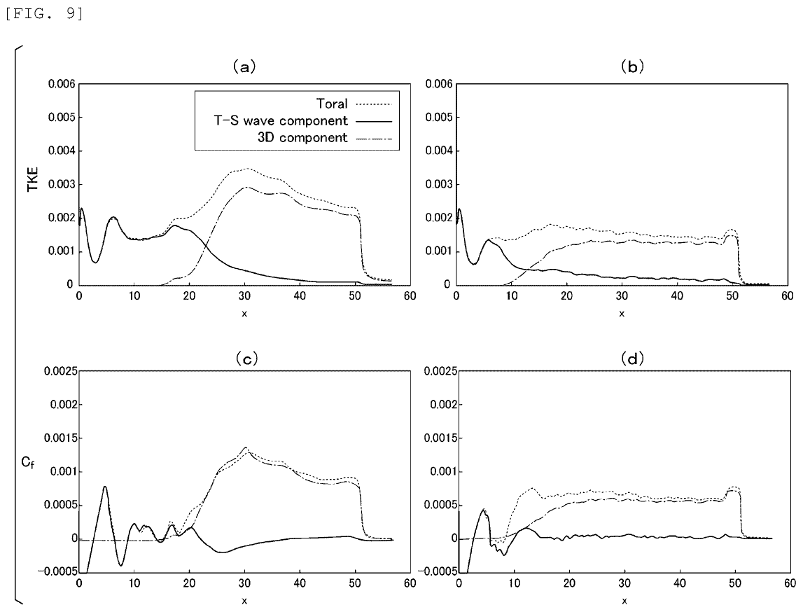

FIG. 8 is a diagram illustrating a maximum value of turbulent kinetic energy along the x direction for each type of rough surface according to the embodiment. As an example of a case where a rough surface provided by the evaluation device according to the embodiment is used, a sandy rough surface is illustrated. As comparative examples, the wavy roughness (VP), the wavy roughness (BF), and smooth (flat plate or smooth surface) are also illustrated. As is apparent from the drawing, it can be seen that, at the sandy rough surface, the generation of a disturbance caused by collapse of a T-S wave after its growth is restricted since the collapse of the T-S wave occurs at an early stage. That is, from the drawing, it was found that, at the sandy rough surface, a turbulent kinetic energy TKE was most restricted.

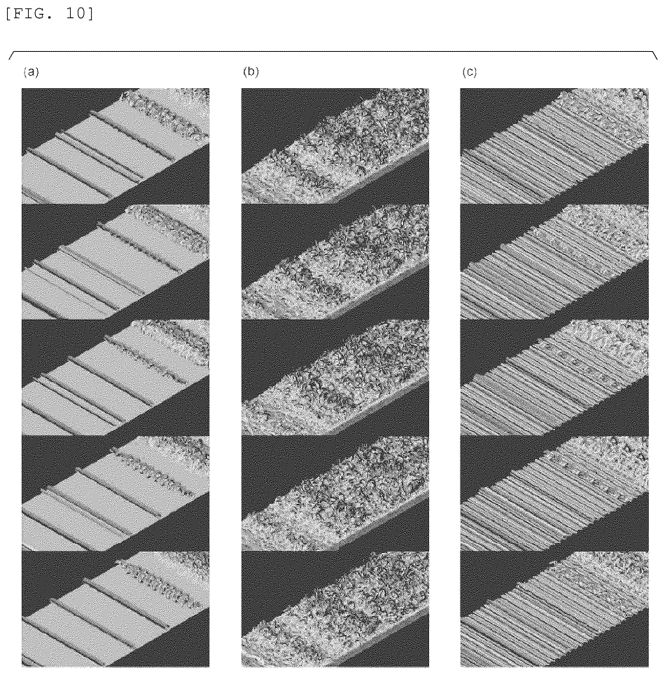

FIG. 9 is a diagram illustrating a change along the X direction, regarding a decomposition integral value of the turbulent kinetic energy in the Z direction and a frictional resistance coefficient value according to the embodiment. (a) of FIG. 9 and (b) of FIG. 9 illustrate changes along the X direction of the decomposition integral value of the turbulent kinetic energy in the Z direction. (c) of FIG. 9 and (d) of FIG. 9 illustrate changes along the X direction of the frictional resistance coefficient value. (a) of FIG. 9 and (c) of FIG. 9 are examples of a flat plate (smooth surface), and are comparative examples. (b) of FIG. 9 and (d) of FIG. 9 are examples of a sandy rough surface, and illustrate a case where a rough surface provided by the evaluation device according to the embodiment is used. As can be seen from the drawing, at the sandy rough surface, as compared with the flat plate (smooth surface), the decomposition integral value of the turbulent kinetic energy in the Z direction and the frictional resistance coefficient value are restricted to be low.

FIG. 10 is a diagram illustrating a snap shot for each type of rough surface according to the embodiment and illustrating a plurality of snap shots at different time-points. (a) of FIG. 10 is an example of a flat plate (smooth surface), and is a comparative example. (b) of FIG. 10 is an example of a sandy rough surface, and illustrates a case where a rough surface provided by the evaluation device according to the embodiment is used. (c) of FIG. 10 is an example of wavy roughness and is a comparative example. The snap shots show a state in which T-S waves are induced at inlet boundaries, propagate in a flow direction, and are soon destroyed to become a three-dimensional structure. Comparing positions at which roll vortices are destroyed, it can be seen that the destruction in the case where the rough surface provided by the evaluation device according to the embodiment is used among the three cases illustrated is the fastest.

Here, according to the embodiment, phase average decomposition is applied in order to clarify the difference in the transition process based on a T-S wave period. Specifically, turbulent kinetic energy k is divided into k tilde that indicates a T-S wave component and k dash that indicates a three-dimensional component, as shown in the following formula (7).

$$[ Math . 7 ]$$

$$k = \overline{k} + k ' , \qquad ( 7 )$$

Further, the turbulent kinetic energy k is divided into a time-variant term and a time-invariant term, as shown in the following formula (8).

$$[ Math . 8 ]$$

$$k = \overline{k} + \tilde{k} + {k}^{″} . \qquad ( 8 )$$

Here, k bar is a time average (a time-invariant term). Further, k tilde and k two dash are time-variant terms. More specifically, the k tilde indicates a T-S wave component, and the k two dash indicates a three-dimensional component. The k tilde is a term that contributes to non-growth of a roll vortex, and the k two dash is a term that contributes to destruction of a roll vortex. According to the embodiment, since the turbulent kinetic energy k is decomposed into three terms as described above, a roll vortex can be prevented from growing and the roll vortex can be destroyed even if the roll vortex grows.

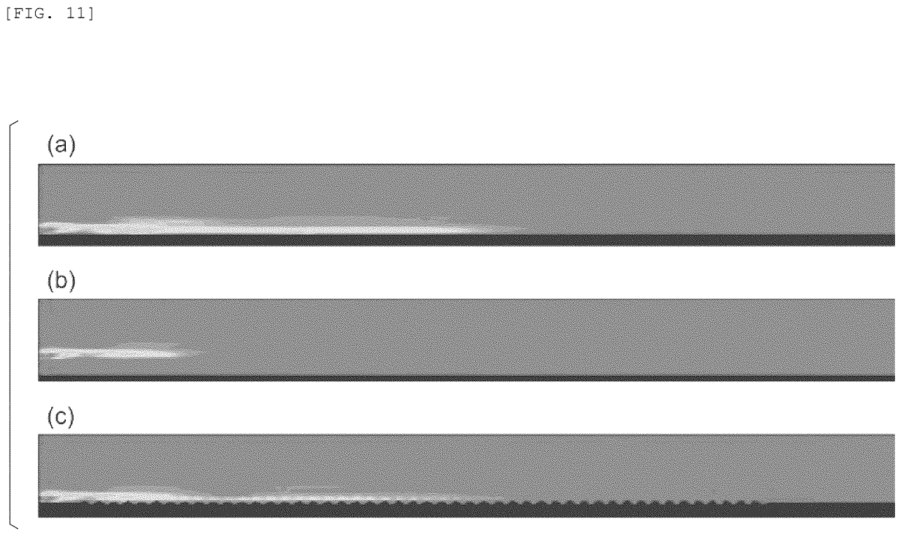

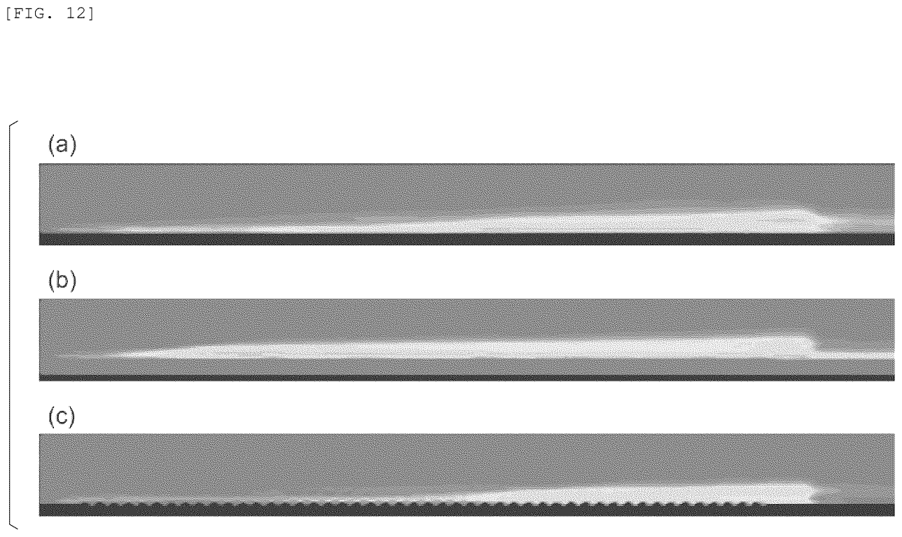

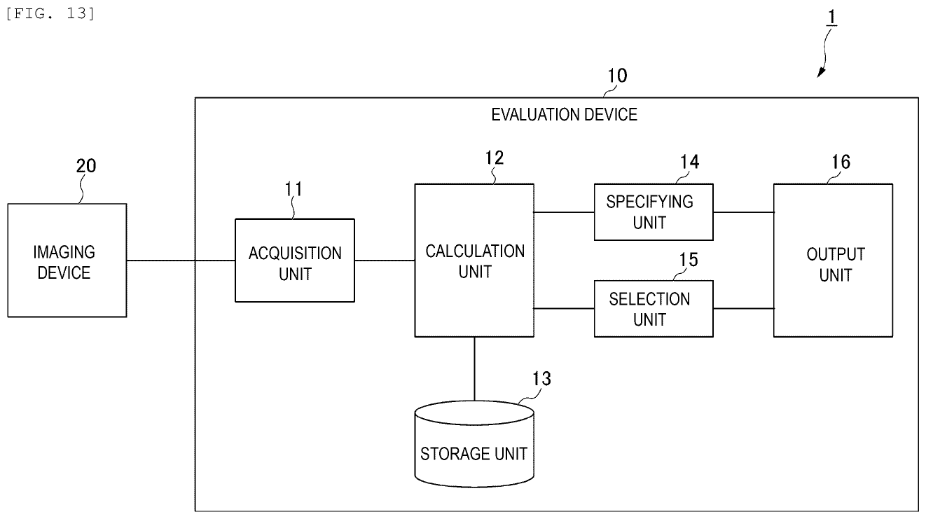

FIG. 11 is a contour map of turbulent kinetic energy averaged in phase, time, and span of a T-S wave component according to the embodiment. FIG. 12 is a contour map of turbulent kinetic energy averaged in phase, time, and span of a T-S wave component three-dimensional structure according to the embodiment. (a) of FIG. 11 and (a) of FIG. 12 are examples of a smooth surface (flat plate), and are comparative examples. (b) of FIG. 11 and (b) of FIG. 12 are examples of a sandy rough surface, and illustrate a case where a rough surface provided by the evaluation device according to the embodiment is used. (c) of FIG. 11 and (c) of FIG. 12 are examples of wavy roughness, and are comparative examples.

Comparing the turbulent kinetic energy k on the three rough surfaces, it can be seen that the turbulent kinetic energy at the sandy rough surface is kept smallest at a downstream side. From decomposition statistics, it can be seen that the sandy rough surface reduces T-S wave kinetic energy with respect to the other two rough surfaces. Further, it can be seen that three-dimensional kinetic energy increases most at an upstream side and decreases at a downstream side. In instantaneous visualization, the sandy rough surface has the most rapid three-dimensional formation. However, the gap weakens a T-S wave motion, and as a result, the total turbulent kinetic energy is reduced at the downstream side. Although the T-S wave kinetic energy is restricted even at the wavy roughness, the total turbulent kinetic energy is larger than that at the sandy rough surface. This is due to a vortex generated at the top of the wavy roughness.

As described above, it was found that the T-S wave weakens at a sandy rough surface. In addition, it was found that, although decomposition of the T-S wave was promoted at the sandy rough surface, the total turbulent kinetic energy and a frictional resistance coefficient value were restricted.

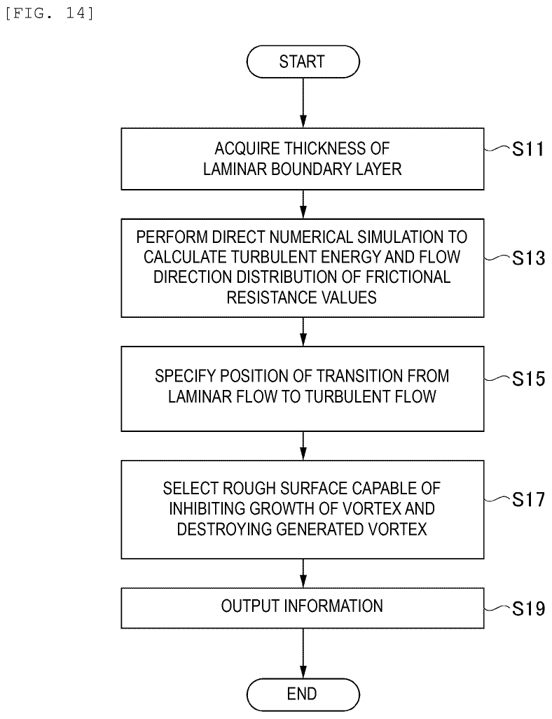

Next, an example of a specific implementation of the evaluation device as described above will be described with reference to FIGS. 13 to 15.

FIG. 13 is a functional configuration diagram illustrating an example of a functional configuration of the evaluation device according to the embodiment. An example of a functional configuration of an evaluation device 10 will be described with reference to the drawing. The evaluation device 10 includes an acquisition unit 11, a calculation unit 12, a storage unit 13, a specifying unit 14, a selection unit 15, and an output unit 16. These functional units are implemented using, for example, an electronic circuit. Each functional unit may internally include a storage unit such as a semiconductor memory or a magnetic hard disk device, if necessary. Further, each function may be implemented by a computer, which includes a central processing unit (CPU), and software.

The acquisition unit 11 acquires the thickness δs of a laminar boundary layer at an inlet of a test section on a rough surface to be evaluated by the evaluation device 10. In the embodiment, for example, the rough surface to be evaluated may be imaged by an imaging device 20, and the acquisition unit 11 may acquire the thickness δs of the laminar boundary layer by performing image processing on image information obtained by imaging the rough surface. The imaging device 20 may be a CCD camera using a charge-coupled device (CCD) image sensor or a CMOS camera using a complementary metal oxide semiconductor (CMOS) image sensor. The image captured by the imaging device 20 may be a color image or a monochrome image. When evaluating a plurality of rough surfaces, the acquisition unit 11 may acquire the thickness δs of the laminar boundary layer on the plurality of rough surfaces.

The calculation unit 12 performs a direct numerical simulation (DNS) based on the acquired thickness δs of the laminar boundary layer to calculate turbulent energy and a direction distribution of frictional resistance flow coefficient values at the rough surface. Specifically, the calculation unit 12 calculates the turbulent energy and the flow direction distribution of frictional resistance coefficient values at the rough surface by using the volume penalization method (VP method) and the zonal method as described above. When evaluating a plurality of rough surfaces, the calculation unit 12 may perform the direct numerical simulation based on the acquired thickness δs of the plurality of laminar boundary layers to calculate the turbulent energy and the flow direction distribution of frictional resistance coefficient values at each of the plurality of rough surfaces.

The storage unit 13 includes, for example, a hard disk drive (HDD), a solid state drive (SSD), a flash memory, and a read only memory (ROM). The storage unit 13 stores parameters and the like used for calculation.

The specifying unit 14 specifies a position of transition from a laminar flow to a turbulent flow based on the turbulent energy and the flow direction distribution of frictional resistance coefficient values at the rough surface, which are calculated by the calculation unit 12.

The selection unit 15 selects a rough surface, which is capable of inhibiting growth of a vortex and destroying a generated vortex, based on the turbulent energy and the flow direction distribution of frictional resistance coefficient values at each of the plurality of rough surfaces, which are calculated by the calculation unit 12. The selection unit 15 decomposes a variable of the Navier-Stokes equation into a time-invariant variable (for example, a time average variable) and a time-variant variable, specifies a wavelength to be amplified when a random number is given as a disturbance, and selects, based on the specified wavelength, a rough surface that is capable of inhibiting growth of a vortex and destroying a generated vortex. For example, the selection unit 15 may decompose the turbulent kinetic energy k into a time-invariant variable and a time-variant variable as shown in the formulas (7) and (8).

The output unit 16 outputs information based on a result calculated by the calculation unit 12. The output unit 16 may output the position of transition that is specified by the specifying unit 14. Further, the output unit 16 may output information on the rough surface selected by the selection unit 15.

The rough surface provided by the evaluation device 10 is a rough surface on which a fluid flows and is a sandy rough surface including a plurality of sand-like protrusions. The rough surface provided by the evaluation device 10 at least includes a first protrusion and a second protrusion as protrusions constituting the sandy rough surface. The first protrusion is based on a first wavelength that is a wavelength capable of inhibiting growth of a vortex. The second protrusion is based on a second wavelength that is a wavelength different from the first wavelength and is capable of destroying a generated vortex. The rough surface provided by the evaluation device 10 does not have an effect only in a predetermined direction like a riblet, but has an effect in various directions. That is, the first protrusion and the second protrusion are provided in both of a first direction and a second direction, the first direction being in parallel to the rough surface and being a vortex advection direction, the second direction being in parallel to the rough surface and orthogonal to the first direction.

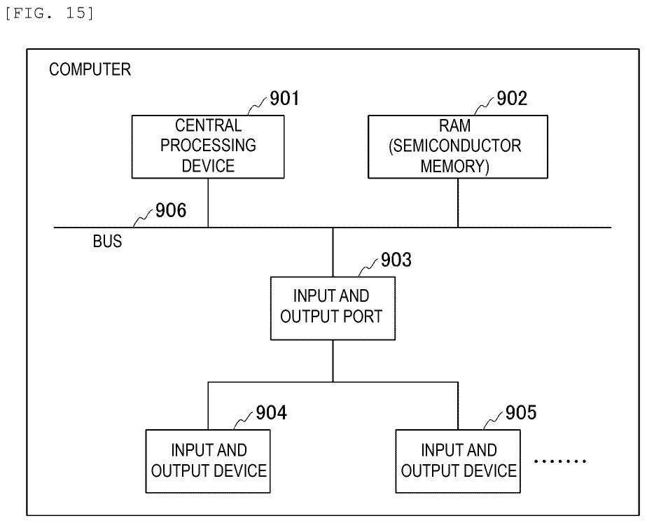

FIG. 14 is a flowchart illustrating an example of an evaluation method according to the embodiment. An example of an evaluation method using the evaluation device 10 according to the embodiment will be described with reference to the drawing. First, the evaluation device 10 acquires the thickness δs of a laminar boundary layer (step S11). Next, the evaluation device 10 performs a direct numerical simulation based on the acquired thickness δs of the laminar boundary layer to calculate turbulent energy and a flow direction distribution of frictional resistance coefficient values (step S13). Next, the evaluation device 10 specifies a position of transition from a laminar flow to a turbulent flow based on a result of calculation (step S15). Further, the evaluation device 10 selects, from a plurality of rough surfaces, a rough surface that is capable of inhibiting growth of a vortex and destroying a generated vortex (step S17). Finally, the evaluation device 10 outputs a calculation result (step S19).

FIG. 15 is a block diagram illustrating an example of an internal configuration of the evaluation device 10 according to the embodiment. At least a part of the functions of the evaluation device 10 may be implemented by using a computer. As illustrated, the computer includes a central processing device 901, a RAM 902, an input and output port 903, input and output devices 904, 905, etc. and a bus 906. The computer itself can be implemented by using an existing technique. The central processing device 901 executes instructions included in a program read from the RAM 902 or the like. The central processing device 901 writes data to the RAM 902, reads data from the RAM 902, and performs an arithmetic operation and a logical operation in accordance with each instruction. The RAM 902 stores data and programs. Each element in the RAM 902 has an address and can be accessed using the address. The RAM is an abbreviation for “random access memory”. The input and output port 903 is a port for the central processing device 901 to exchange data with an external input and output device or the like. The input and output devices 904 and 905 are input and output devices. The input and output devices 904 and 905 exchange data with the central processing device 901 via the input and output port 903. The bus 906 is a common communication path used inside the computer. For example, the central processing device 901 reads or writes data in the RAM 902 via the bus 906. For example, the central processing device 901 accesses the input and output port via the bus 906.

### Summary of Embodiment

As described above, the evaluation device 10 evaluates a test section, in which a laminar flow transitions to a turbulent flow, of a rough surface on which a fluid flows. With the acquisition unit 11, the evaluation device 10 acquires the thickness δs of a laminar boundary layer at an inlet of the test section. With the calculation unit 12, the evaluation device performs a direct numerical simulation based on the acquired thickness δs of the laminar boundary layer and calculates turbulent energy and a flow direction distribution of frictional resistance coefficient values at the rough surface. With the output unit 16, the evaluation device 10 outputs information based on a result of calculation. By adopting such a configuration, it is possible to clarify a mechanism of reducing the frictional resistance by fine distribution roughness by the evaluation device 10.

Further, according to the above-described embodiment, the calculation unit 12 calculates the turbulent energy and the flow direction distribution of frictional resistance coefficient values at the rough surface by using a volume penalization method (VP method) and a zonal method. Therefore, according to the embodiment, the calculation can be performed by a direct numerical simulation.

According to the above-described embodiment, the acquisition unit 11 acquires the thickness δs of the laminar boundary layer at the inlet of the test section based on an image obtained by imaging the rough surface. That is, according to the embodiment, the evaluation device 10 performs evaluation based on image information obtained by imaging the rough surface on which a fluid flows. Therefore, according to the embodiment, the rough surface can be evaluated easily.

Further, according to the above-described embodiment, since the specifying unit 14 is further provided, the position of transition from the laminar flow to the turbulent flow is specified based on the calculated turbulent energy and flow direction distribution of frictional resistance coefficient values at the rough surface. Therefore, according to the embodiment, the evaluation device 10 can specify the position of transition from the laminar flow to the turbulent flow.

Further, according to the above-described embodiment, the acquisition unit 11 acquires the thickness δs of the laminar boundary layer for a plurality of rough surfaces, and the calculation unit 12 performs a direct numerical simulation based on the acquired thickness δs of a plurality of laminar boundary layers, thereby calculating the turbulent energy and the flow direction distribution of frictional resistance coefficient values at each of the plurality of rough surfaces. Further, with the selection unit 15, the evaluation device 10 selects a rough surface, which is capable of inhibiting growth of a vortex and destroying a generated vortex, based on the calculated turbulent energy and flow direction distribution of frictional resistance coefficient values at each of the plurality of rough surfaces. Therefore, according to the embodiment, it is possible to select a rough surface capable of efficiently reducing the frictional resistance.

Further, according to the above-described embodiment, the selection unit 15 decomposes a variable of a Navier-Stokes equation into a time-invariant variable and a time-variant variable, specifies a wavelength to be amplified when a random number is given as a disturbance to each of the plurality of rough surfaces, and selects, based on the specified wavelength, a rough surface that is capable of inhibiting growth of a vortex and destroying a generated vortex. Therefore, according to the embodiment, it is possible to select a rough surface, which is capable of efficiently reducing the frictional resistance, by a direct numerical simulation.

Further, according to the above-described embodiment, it is possible to provide a rough surface on which a fluid flows and which is selected using the evaluation device 10 as described above. Therefore, according to the embodiment, it is possible to provide a rough surface capable of reducing the frictional resistance.

Further, according to the above-described embodiment, the rough surface of the embodiment includes a first protrusion based on a first wavelength that is a wavelength capable of inhibiting growth of a vortex, and a second protrusion based on a second wavelength that is a wavelength different from the first wavelength and is capable of destroying a generated vortex. The first protrusion and the second protrusion are provided in both of a first direction and a second direction, the first direction being in parallel to the rough surface, the second direction being in parallel to the rough surface and orthogonal to the first direction. With such protrusions, the rough surface according to the embodiment can reduce the frictional resistance in any direction without specifying a direction having an effect.

Although an embodiment for implementing the invention has been described using the embodiment, the invention is not limited to the embodiment, and various modifications and replacements can be made in a range not departing from the gist of the invention.

Further, a computer program for implementing the functions of the above-described devices may be recorded in a computer-readable recording medium, and the program recorded in the recording medium may be read and executed by a computer system. Here, the “computer system” may include an OS and hardware such as peripheral devices.

The “computer-readable recording medium” refers to a flexible disk, a magneto-optical disk, a ROM, a writable non-volatile memory such as a flash memory, a portable medium such as a digital versatile disc (DVD), and a storage device such as a hard disk built in a computer system.

Further, the “computer-readable recording medium” includes a medium that holds a program for a certain period of time, such as a volatile memory (for example, a dynamic random access memory (DRAM)) inside a computer system that serves as a server or a client when the program is transmitted via a network such as the Internet or a communication line such as a telephone line. The program may be transmitted from a computer system, in which the program is stored in a storage device or the like, to another computer system via a transmission medium or a transmission wave in a transmission medium. Here, the “transmission medium” that transmits the program refers to a medium having a function of transmitting information, for example, a network (communication network) such as the Internet or a communication line such as a telephone line. The program may implement some of the functions described above. Further, the program may be a so-called differential file (differential program) that can implement the above-described functions in combination with a program already recorded in the computer system.

### REFERENCE SIGNS LIST

1: evaluation system
10: evaluation device
11: acquisition unit
12: calculation unit
13: storage unit
14: specifying unit
15: selection unit
16: output unit
20: imaging device

1. An evaluation device for evaluating a test section, in which a laminar flow transitions to a turbulent flow, of a rough surface on which a fluid flows, the evaluation device comprising:
an acquisition unit configured to acquire a thickness of a laminar boundary layer at an inlet of the test section;
a calculation unit configured to calculate turbulent energy and a flow direction distribution of frictional resistance coefficient values at the rough surface by performing a direct numerical simulation based on the acquired thickness of the laminar boundary layer; and
an output unit configured to output information based on a result of calculation.

2. The evaluation device according to claim 1, wherein
the calculation unit calculates the turbulent energy and the flow direction distribution of frictional resistance coefficient values at the rough surface by using a volume penalization method (VP method) and a zonal method.

3. The evaluation device according to claim 1, wherein
the acquisition unit acquires the thickness of the laminar boundary layer at the inlet of the test section based on an image obtained by imaging the rough surface.

4. The evaluation device according to claim 1, further comprising:
a specifying unit configured to specify a position of transition from the laminar flow to the turbulent flow based on the calculated turbulent energy and flow direction distribution of frictional resistance coefficient values at the rough surface, wherein
the output unit outputs the specified position of transition.

5. The evaluation device according to claim 1, further comprising:
a selection unit, wherein
the acquisition unit acquires the thickness of the laminar boundary layer at the inlet of the test section for a plurality of the rough surfaces,
the calculation unit calculates the turbulent energy and the flow direction distribution of frictional resistance coefficient values at each of the plurality of the rough surfaces by performing a direct numerical simulation based on the acquired thicknesses of the plurality of laminar boundary layers, and
the selection unit selects the rough surface, which is capable of inhibiting growth of a vortex and destroying a generated vortex, based on the calculated turbulent energy and flow direction distribution of frictional resistance coefficient values at each of the plurality of the rough surfaces.

6. The evaluation device according to claim 5, wherein
the selection unit decomposes variables of a Navier-Stokes equation into a time-invariant variable and a time-variant variable, and selects, based on a wavelength of a vortex amplified when a random number is given as a disturbance, the rough surface capable of inhibiting growth of a vortex and promoting nullification by destroying a generated vortex.

7. A rough surface that is a rough surface on which a fluid flows, wherein
the rough surface is selected by the evaluation device according to claim 5.

8. The rough surface according to claim 7, comprising:
a first protrusion based on a first wavelength that is a wavelength capable of inhibiting growth of a vortex; and
a second protrusion based on a second wavelength that is a wavelength different from the first wavelength and is capable of promoting destruction of a generated vortex, wherein
the first protrusion and the second protrusion are provided in both of a first direction and a second direction, the first direction being in parallel to the rough surface and being a vortex advection direction, the second direction being in parallel to the rough surface and orthogonal to the first direction.

9. An evaluation method for evaluating a test section, in which a laminar flow transitions to a turbulent flow, of a rough surface on which a fluid flows, the evaluation method comprising:
an acquisition step of acquiring a thickness of a laminar boundary layer at an inlet of the test section;
a calculation step of calculating turbulent energy and a flow direction distribution of frictional resistance coefficient values at the rough surface by performing a direct numerical simulation based on the acquired thickness of the laminar boundary layer; and
an output step of outputting information based on a result of calculation.

10. A non-transitory computer readable storage media storing a program for evaluating a test section, in which a laminar flow transitions to a turbulent flow, of a rough surface on which a fluid flows, the program causing a computer to execute:
acquiring a thickness of a laminar boundary layer at an inlet of the test section;
calculating turbulent energy and a flow direction distribution of frictional resistance coefficient values at the rough surface by performing a direct numerical simulation based on the acquired thickness of the laminar boundary layer; and
outputting information based on a result of calculation.

11. The evaluation device according to claim 2, wherein
the acquisition unit acquires the thickness of the laminar boundary layer at the inlet of the test section based on an image obtained by imaging the rough surface.

12. The evaluation device according to claim 2, further comprising:
a specifying unit configured to specify a position of transition from the laminar flow to the turbulent flow based on the calculated turbulent energy and flow direction distribution of frictional resistance coefficient values at the rough surface, wherein
the output unit outputs the specified position of transition.

13. A rough surface that is a rough surface on which a fluid flows, wherein
the rough surface is selected by the evaluation device according to claim 6.

14. The rough surface according to claim 13, comprising:
a first protrusion based on a first wavelength that is a wavelength capable of inhibiting growth of a vortex; and
a second protrusion based on a second wavelength that is a wavelength different from the first wavelength and is capable of promoting destruction of a generated vortex, wherein
the first protrusion and the second protrusion are provided in both of a first direction and a second direction, the first direction being in parallel to the rough surface and being a vortex advection direction, the second direction being in parallel to the rough surface and orthogonal to the first direction.
